(19) United States
(12) Patent Application Publication
(10) Pub. No.: US 2025/0138431 A1
(43) Pub. Date: May 1, 2025

(54) METHOD OF CONFIGURING EXTREME ULTRA-VIOLET (EUV) LIGHT SOURCE AND EUV EXPOSURE METHOD USING THE EUV LIGHT SOURCE

(71) Applicant: SAMSUNG ELECTRONICS CO., LTD., SUWON-SI (KR)

(72) Inventors: Sungmin Nam, Suwon-si (KR); Seongjeon Choi, Suwon-si (KR); Seunghune Yang, Suwon-si (KR)

(21) Appl. No.: 18/677,041

(22) Filed: May 29, 2024

(30) Foreign Application Priority Data
Oct. 31, 2023 (KR) 10-2023-0148435

(51) Int. Cl. G03F 7/00

(52) U.S. Cl. CPC G03F 7/70125; G03F 7/70433; G03F 7/705

(57) ABSTRACT

A method of configuring an extreme ultraviolet (EUV) light source includes obtaining first information about a mask pattern, generating a top-hat illumination system for the mask pattern based on a Fourier approximation, storing second information about aerial images of EUV point light sources that correspond to pupil mirrors, selecting a combination of the EUV point light sources according to established rules, and performing a simulation on an entire EUV illumination system, based on the selected combination of the EUV point light sources.

### CROSS-REFERENCE TO RELATED APPLICATION

This application claims priority under 35 U.S.C. § 119 from Korean Patent Application No. 10-2023-0148435, filed on Oct. 31, 2023 in the Korean Intellectual Property Office, the contents of which are herein incorporated by reference in their entirety.

### TECHNICAL FIELD

Embodiments of the inventive concept are directed to an extreme ultraviolet (EUV) light source, and more particularly, to a method of configuring an EUV light source that optimizes an EUV illumination system and an EUV exposure method that uses the EUV light source.

### DISCUSSION OF THE RELATED ART

As the linewidths of semiconductor circuits have become gradually finer, light sources with shorter wavelengths have been used. For example, extreme ultraviolet (EUV) light is used as an exposure light source, and the number of layers that essentially use EUV as the exposure light source has been gradually increased. Due to the absorption characteristics of EUV, a reflective EUV mask is typically used in an EUV exposure process. In addition, each of an illumination optics that transmit EUV to the EUV mask and a projection optics that project EUV reflected from the EUV mask onto an exposure target includes a plurality of mirrors.

### SUMMARY

Embodiments of the inventive concept provide a method of configuring an extreme ultraviolet (EUV) light source for an optimized EUV illumination system and an EUV exposure method that uses the EUV light source.

According to an embodiment of the inventive concept, there is provided a method of configuring an EUV light source. The method includes obtaining first information about a mask pattern, generating a top-hat illumination system for the mask pattern based on a Fourier approximation, storing second information about aerial images of EUV point light sources that correspond to pupil mirrors, selecting a combination of the EUV point light sources according to established rules, and performing a simulation on an entire EUV illumination system based on the selected combination of the EUV point light sources.

According to another embodiment of the inventive concept, there is provided a method of configuring an EUV light source. The method includes obtaining first information about a mask pattern, generating a top-hat illumination system based on two-dimensional (2D) fast Fourier transform (FFT) images of the mask pattern and a target pattern, storing second information about aerial images by performing, based on the top-hat illumination system, an optical simulation on EUV point light sources that corresponds to some pupil mirrors, selecting a combination of the EUV point light sources according to established rules that satisfy a constraint and maximize a normalized image log slope (NILS), and performing a simulation on an entire EUV illumination system, based on the selected combination of the EUV point light sources.

According to another embodiment of the inventive concept, there is provided an EUV exposure method that includes preparing an EUV mask, configuring an EUV light source that corresponds to the EUV mask, and performing an EUV exposure on a wafer by using the EUV light source, wherein configuring the EUV light source includes obtaining first information about a mask pattern, generating a top-hat illumination system for the mask pattern based on a Fourier approximation, storing second information about aerial images of EUV point light sources that correspond to pupil mirrors, selecting a combination of the EUV point light sources according to established rules, and performing a simulation on an entire EUV illumination system based on the selected combination of the EUV point light sources.

### BRIEF DESCRIPTION OF THE DRAWINGS

FIG. 1 is a flowchart of a method of configuring an extreme ultraviolet (EUV) light source, according to an embodiment.

FIG. 2A illustrates EUV equipment for a method of configuring an EUV light source illustrated in FIG. 1, and FIG. 2B illustrates EUV mapping in a method of configuring an EUV light source illustrated in FIG. 1.

FIG. 3 illustrates EUV point light sources in a method of configuring an EUV light source illustrated in FIG. 1.

FIG. 4 is a flowchart of generating a Fourier approximation top-hat illumination system in a method of configuring an EUV light source, which is shown in FIG. 1.

FIGS. 5A to 5D illustrate the generation of the Fourier approximation top-hat illumination system illustrated FIG. 4.

FIGS. 6A and 6B illustrate a generation of a different type of Fourier approximation top-hat illumination system.

FIG. 7 illustrates concepts and calculation of a target critical dimension (CD) and a normalized image log slope (NILS) in a method of configuring an EUV light source illustrated in FIG. 1.

FIG. 8 is a flowchart of selecting a combination of EUV point light sources in a method of configuring an EUV light source illustrated in FIG. 1.

FIGS. 9A to 10B illustrate an operation of selecting a combination of EUV point light sources illustrated in FIG. 8.

FIG. 11 is a flowchart an EUV exposure method that uses an EUV light source, according to an embodiment.

### DETAILED DESCRIPTION OF THE EMBODIMENTS

Hereinafter, embodiments will be described in detail with reference to the accompanying drawings. The same reference numerals may be used to denote the same elements in the drawings, and repeated descriptions thereof may be omitted.

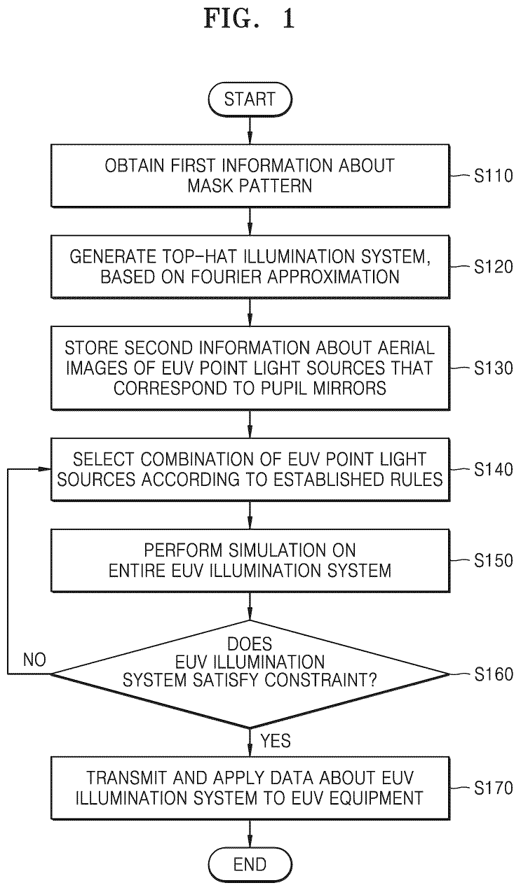

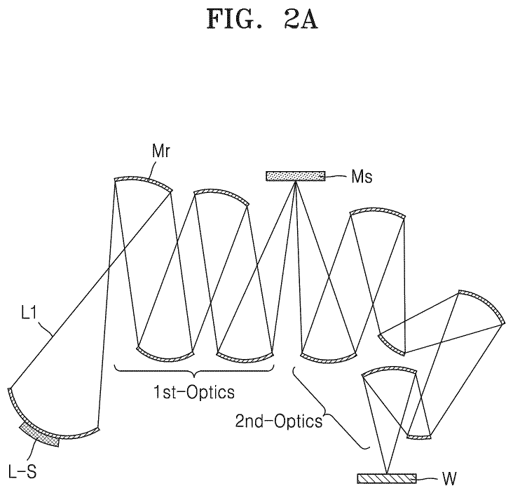

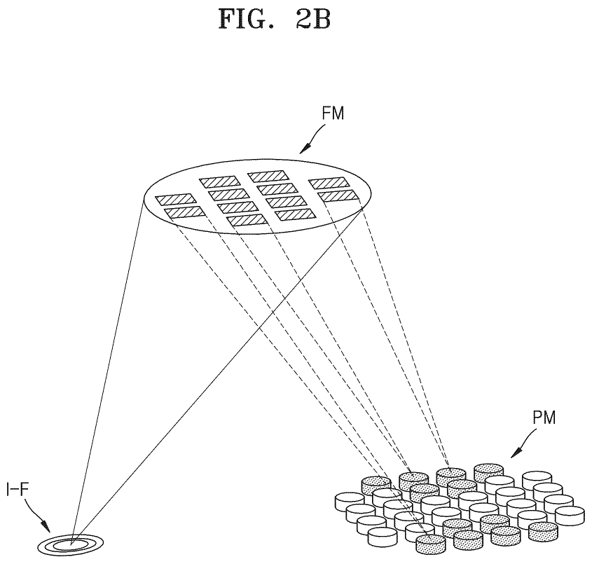

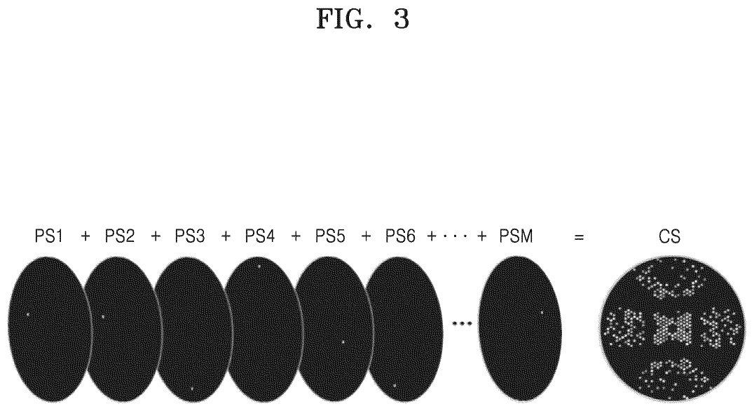

FIG. 1 is a flowchart of a method of configuring an extreme ultraviolet (EUV) light source, according to an embodiment. FIG. 2A illustrates EUV equipment used in a method of configuring an EUV light source illustrated in FIG. 1, and FIG. 2B illustrated EUV mapping in a method of configuring an EUV light source illustrated in FIG. 1. FIG. 3 illustrates EUV point light sources in a method of configuring an EUV light source illustrated in FIG. 1.

Referring to FIGS. 1 and 2A, before describing a method of configuring an EUV light source according to a present embodiment, the EUV equipment is described. The EUV equipment includes an EUV light source L-S, a first optics 1st-Optics, a second optics 2nd-Optics, an EUV mask Ms, and a wafer W. The EUV light source L-S generates and outputs EUV light L1 with high energy density within a wavelength range of about 5 nm to about 50 nm. For example, the EUV light source L-S generates and outputs EUV light L1 of high energy density with a wavelength of 13.5 nm. The EUV light source L-S may be a plasma-based light source or a synchrotron radiation light source. The plasma-based light source generates plasma and uses light emitted by the plasma. The plasma-based light source may include a laser-produced plasma (LPP) light source or a discharge-produced plasma (DPP) light source.

The first optics 1st-Optics includes a plurality of mirrors. For example, the first optics 1st-Optics includes two to five mirrors Mr. However, the number of mirrors of the first optics 1st-Optics is not necessarily limited thereto. The first optics 1st-Optics may be referred to as an EUV illumination optics or an EUV illumination system. In a method of configuring the EUV light source according to the present embodiment, the EUV light source includes the EUV light source L-S, the first optics 1st-Optics, and the second optics 2nd-Optics. However, in some embodiments, the EUV light source is synonymous with the EUV illumination system.

The first optics 1st-Optics transmits EUV light L1 from the EUV light source L-S to the EUV mask Ms. For example, the EUV light L1 is reflected by the mirrors Mr in the first optics 1st-Optics and is incident on the EUV mask Ms. In addition, the first optics 1st-Optics transmits the EUV light L1 in the form of a curved slit to enter the EUV mask Ms. A curved slit form of EUV light refers to a parabolic 2D curve on an x-y plane.

The EUV mask Ms is a reflective mask that includes a reflective region and a non-reflective and/or intermediate reflective region. The EUV mask Ms includes a substrate that includes a low thermal-expansion coefficient material (LTEM), such as quartz, a reflective multilayered film on the substrate that reflects EUV light, and an absorption layer formed on the reflective multilayered film. The reflective multilayered film has, for example, a structure in which a molybdenum (Mo) layer and a silicon (Si) layer are alternately stacked in a plurality of layers. In addition, the absorption layer may include, for example, at least one of tantalum nitride (TaN), tantalum oxynitride (TaNO), tantalum borate (TaBO), nickel (Ni), gold (Au), silver (Ag), carbon (C), tellurium (Te), platinum (Pt), palladium (Pd), or chromium (Cr). However, a material of the reflective multilayered film and a material of the absorption layer are not necessarily limited to the above-described materials. In some embodiments, the absorption layer corresponds to the non-reflective and/or intermediate reflective region.

The EUV mask Ms reflects the EUV light L1 that is incident through the first optics 1st-Optics, and the reflected EUV light L1 enters the second optics 2nd-Optics. For example, the EUV mask Ms reflects the EUV light L1 from the first optics 1st-Optics. For example, the EUV mask Ms structures the EUV light L1 according to a shape of a pattern formed by the reflective multilayered film and the absorption layer on the substrate and so that the structuralized EUV light L1 can enter the second optics 2nd-Optics. The EUV light L1 includes at least secondary diffracted light, based on the pattern on the EUV mask Ms. The structured EUV light L1 is incident on the second optics 2nd-Optics while retaining pattern-type information of the EUV mask Ms, and is projected onto an EUV exposure target, such as the wafer W, through the second optics 2nd-Optics. The second optics 2nd-Optics may be referred to as an EUV projection optics. The second optics 2nd-Optics includes a plurality of mirrors. For example, the second optics 2nd-Optics includes four to eight mirrors. However, the number of mirrors of the second optics 2nd-Optics is not necessarily limited thereto.

The EUV mask Ms is disposed on a mask stage. The EUV mask Ms can move in an x direction, a y direction, or a z direction by moving the mask stage, and can also rotate about an x-axis, a y-axis, or a z-axis. The wafer W, which is subject to EUV exposure, is disposed on a wafer stage. The wafer W can move in the x direction, the y direction, or the z direction by moving the wafer stage, and can also rotate about the x-axis, the y-axis, or the z-axis.

First, a method of configuring an EUV light source according to a present embodiment includes obtaining first information about a mask pattern (S110). For example, when the mask pattern is a repetitive pattern, the first information includes a pitch of the repetitive pattern, a target critical dimension (CD), constraints, and a gauge of the mask pattern. For example, the constraints include optical parameters, such as a CD aspect ratio, a dose, a normalized image log slope (NILS), an in-point uniformity (IPU), a mask error enhancement factor (MEEF), and a depth of focus (DoF). However, the constraints are not necessarily limited to the optical parameters. For reference, the NILS is an optical parameter that shows that larger NILS values correspond to smaller CD changes in response to a process variation. In addition, the optical parameters can be used for calculating a cost function or a fitness value. In addition, the gauge of the mask pattern is a one-dimensional (1D) line extracted in relation to an optical parameter of an optimization target. The gauge usually refers to x-axial and y-axial cutlines of a mask pattern.

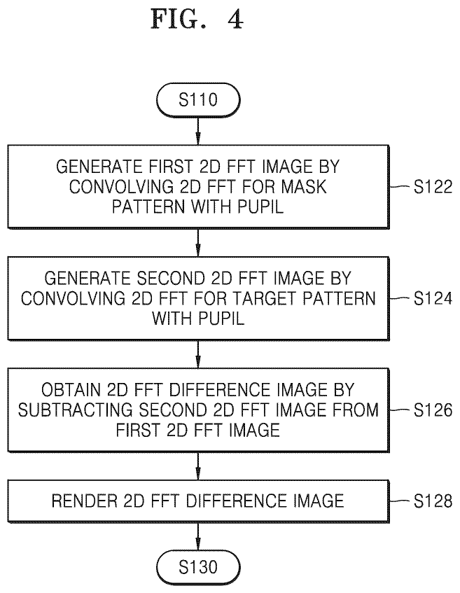

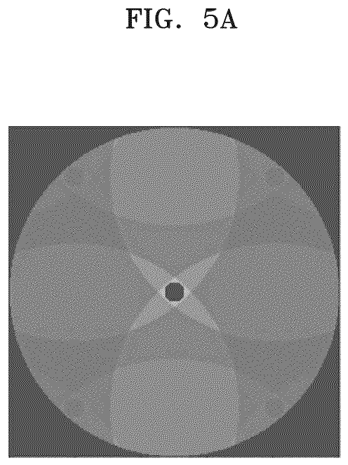

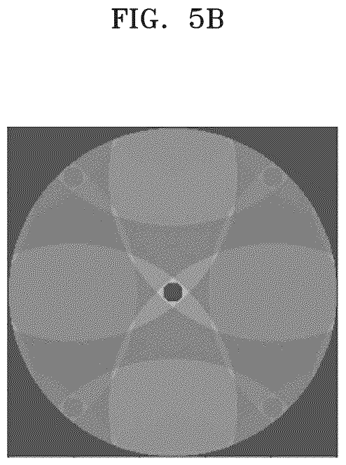

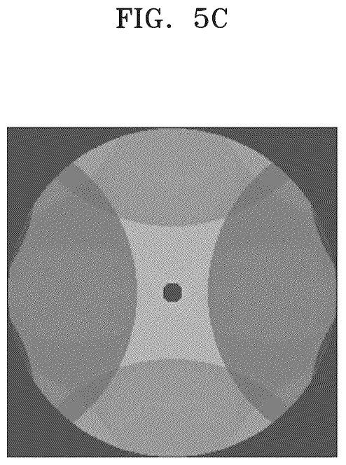

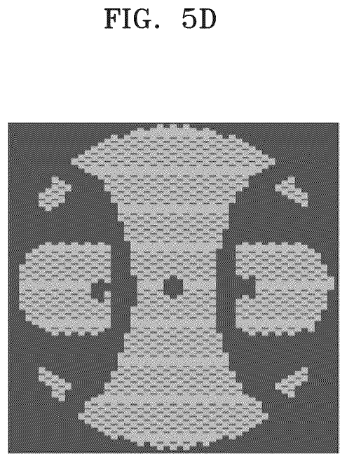

After the first information is obtained, a top-hat illumination system for the mask pattern is generated based on a Fourier approximation (S120). The top-hat illumination system is used to exclude EUV point light sources that are unnecessary for the EUV illumination system. The unnecessary EUV point light sources are excluded by using the top-hat illumination system before aerial images of EUV point light sources are calculated, and thus the time for calculating the aerial images is greatly reduced. An operation of generating the top-hat illumination system is described in further detail with reference to FIGS. 4 to 5D.

In addition, the EUV point light source is a minimum unit that can be individually turned on and off, and be generated by segmenting the EUV illumination system. The segmentation of the EUV illumination system into the EUV point light sources is described below with reference to EUV mapping.

Referring to FIGS. 1 to 2B, in an embodiment, when EUV light from the EUV light source L-S is focused midway before being focused on the EUV mask Ms, the EUV light is referred to as intermediate focusing light I-F. For example, the first optics 1st-Optics transmits the intermediate focusing light I-F to be incident on the EUV mask Ms. Accordingly, as shown in FIG. 2B, the intermediate focusing light I-F transmitted through the first optics 1st-Optics corresponds to a field mirror FM and a pupil mirror PM. For example, the field mirror FM represents an electromagnetic field of EUV light transmitted through the first optics 1st-Optics, and the pupil mirror PM represents an electromagnetic field of EUV light incident on a pupil surface of the EUV mask Ms. For reference, a field mirror may be referred to as a field facet mirror, and a pupil mirror may be referred to as a pupil facet mirror. In general, in the EUV equipment, an optical path from M, where M is a positive integer, field mirrors FM to N, where N is an integer greater than M, pupil mirrors PM is selected. The selection of an optical path from the field mirrors FM to the pupil mirrors PM corresponds to so-called EUV mapping.

For example, in a method of configuring the EUV light source according to a present embodiment, the EUV equipment includes 336 field mirrors FM and 1620 pupil mirrors PM. Due to EUV mapping, of the 1620 pupil mirrors PM, 336 pupil mirrors PM that correspond to the 336 field mirrors FM are selected. Accordingly, the 336 pupil mirrors PM selected by the EUV mapping or EUV light reflected by the 336 pupil mirrors PM correspond to the EUV point light sources. As a result, the selection of the 336 pupil mirrors PM corresponds to selecting locations of the EUV point light sources.

In addition, there can be many combinations of pupil mirrors PM by EUV mapping or combinations of EUV point light sources. However, EUV mapping is usually performed so that one field mirror FM selects one of four or five pupil mirrors PM. Accordingly, four or five pupil mirrors PM of the 1620 pupil mirrors PM correspond to each of the 336 field mirrors FM. Hereinafter, pupil mirrors PM selected by EUV mapping are assumed to be synonymous with EUV point light sources, and the EUV point light sources are adopted and described.

Each of the EUV point light sources segmented from the EUV illumination system are incoherent. For example, light originating from the EUV point light sources at different locations do not interfere with each other. Therefore, the EUV point light sources are treated independently of each other. In addition, the entire EUV illumination system is configured by summing the EUV point light sources. For example, the entire EUV illumination system is configured by summing 336 EUV point light sources. FIG. 3 shows that all incoherent EUV point light sources PS1, PS2, PS3, . . . , and PSM combine to form a cumulative source CS. The cumulative source CS corresponds to the EUV illumination system. In addition, conversely, the EUV illumination system, such as the cumulative source CS, is segmented into EUV point light sources. In FIG. 3, M of PSM is, for example, 336.

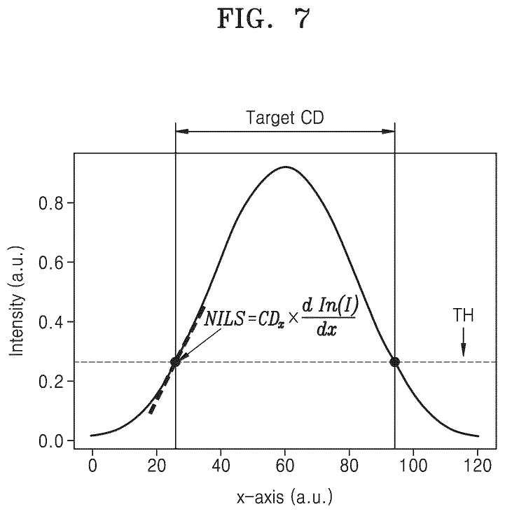

After the top-hat illumination system is generated, second information about aerial images of EUV point light sources that correspond to pupil mirrors is stored (S130). For example, an aerial image of each of the EUV point light sources is calculated by optical simulation, and second information about the aerial images is stored. The second information includes, for example, an intensity on a gauge, a threshold intensity, and an NILS about the aerial images. The aerial image refers to, for example, the EUV point light source by an x-axial intensity profile and a y-axial intensity profile. Gauge information, such as information about the x-axial cutline and the y-axial cutline, is used to calculate the x-axial and y-axial intensity profiles on the x-axial and y-axial cutlines. The threshold intensity and the NILS are described in detail with reference to FIG. 7.

The optical simulation is a process of calculating the intensity of light from a light source in two-dimensions (2D) or in one-dimension (1D) and is performed by a simulation tool. In a method of configuring the EUV light source according to a present embodiment, optical simulation is not limited to a specific software tool and can be performed by using any type of simulation tool if the intensity of light is calculated in 2D or 1D.

In general, in a calculation of aerial images of the EUV point light sources, aerial images of a total of 1620 EUV point light sources are calculated to correspond to 1620 pupil mirrors PM. However, in a method of configuring the EUV light source according to a present embodiment, pupil mirrors PM that are unnecessary for the EUV illumination system or EUV point light sources that correspond to the unnecessary pupil mirrors PM are excluded in advance through a Fourier approximation top-hat illumination system. Accordingly, a calculation of the aerial images of the EUV point light sources is performed fewer then 1,620 EUV point light sources, for example, about 1100 EUV point light sources. In addition, only the second information about aerial images of, for example, the about 1100 EUV point light sources is used.

To configure an EUV illumination system, the aerial images of the EUV point light sources are summed. For example, the aerial images are summed by considering EUV mapping. As described above, EUV mapping refers to selecting an optical path from the field mirrors FM to the pupil mirrors PM. In addition, the summation of aerial images corresponds to summing aerial images of 336 EUV point light sources at locations of 336 pupil mirrors PM selected by EUV mapping. However, EUV mapping can be performed several times to find an optimum EUV illumination system. Accordingly, summation of aerial images is performed several times. However, aerial images of EUV point light sources at all locations, such as EUV point light sources that correspond to all pupil mirrors PM, are calculated and stored in advance. Accordingly, a process of summing various combinations of aerial images due to EUV mapping does not take much time. In a method of configuring the EUV light source according to a present embodiment, by excluding unnecessary EUV point light sources through the Fourier approximation top-hat illumination system, only aerial images of about 1100 EUV point light sources are calculated.

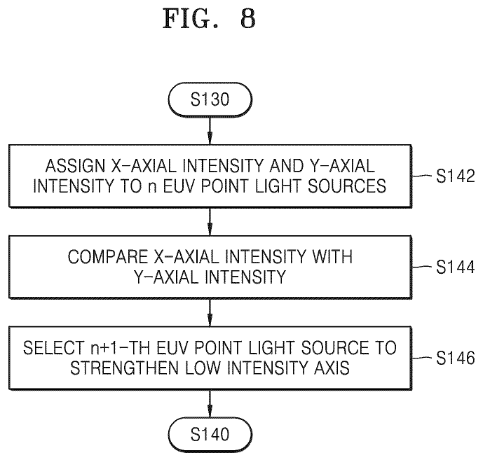

After the second information is stored, a combination of EUV point light sources is selected based on established rules (S140). For example, a selection of the combination of EUV point light sources corresponds to a selection of a combination of EUV mappings. In a method of configuring the EUV light source according to a present embodiment, to implement the optimum EUV illumination system, the combination of EUV point light sources are selected by applying established rules, such as from game theory. For example, in a method of configuring the EUV light source according to a present embodiment, a combination of EUV point light sources that maximizes the NILS while satisfying a constraint is selected according to the rules. The selection of the combination of EUV point light sources is described in further detail with reference to FIGS. 8 to 10B.

After the combination of EUV point light sources is selected, a simulation is performed on the entire EUV illumination system based on the selected combination of EUV point light sources (S150). For example, the simulation is a process of controlling the selected EUV point light sources to be applicable to the EUV equipment that implements the EUV illumination system.

After the simulation, it is determined whether the EUV illumination system satisfies the constraint (S160). For example, when the constraint is a CD aspect ratio, it is determined whether the EUV illumination system is within a set range of the CD aspect ratio. For example, the CD aspect ratio is determined by comparing an X-axis CD with a y-axis CD in the entire aerial image that is calculated by summing aerial images of the EUV illumination system, such as the EUV point light sources.

If the constraints are satisfied (YES), data about the EUV illumination system due to the simulation is transmitted and applied to the EUV equipment (S170). If the constraints are not satisfied (NO), the process proceeds to operation S140 of selecting the combination of EUV point light sources, and thus, a new combination of EUV point light sources is selected.

As a patterning pitch and a CD become smaller, various optical parameters, such as an NILS, a DoF, and an MEEF, related to optical patterning quality are becoming more important. In a method of configuring an EUV light source according to a present embodiment, based on the Fourier approximation top-hat illumination system, an optimum EUV illumination system is implemented by selecting a combination of EUV point light sources according to established rules. In a method of configuring an EUV light source according to a present embodiment, to implement the EUV illumination system, optical parameters that are critical for EUV patterning are optimized, and custom cost functions are set.

For example, in a method of configuring an EUV light source according to a present embodiment, by optimizing the EUV illumination system by generating and summing the aerial images of EUV point light sources, a time for optimizing the EUV illumination system is greatly reduced. In addition, EUV point light sources that are unnecessary for the EUV illumination system are excluded in advance through the Fourier approximation top-hat illumination system. Thus, a time for calculating the aerial images of the EUV point light sources via an optical simulation and a time for storing information about the aerial images is further reduced. Furthermore, a combination of EUV point light sources that minimizes a cost function while satisfying constraints can be selected by applying established rules, such as from game theory, and thus, an optimum EUV illumination system with excellent performance can be implemented. By including constraints or optical parameters in a cost function, the optimization of a more aggressive and efficient EUV illumination system can be performed.

A method of configuring an EUV light source according to a present embodiment is briefly summarized. When a pitch of a mask pattern, a target CD, and constraints, such as an MEEF, a CD aspect ratio, and a dose, are input, a Fourier approximation top-hat illumination system is generated. Aerial images of selected EUV point light sources are calculated via optical simulation. An illumination system is optimized based on the aerial images according to established rules, such as from game theory. Finally, data about the EUV illumination system that minimizes the cost function or maximizes an optimization value while satisfying the constraints is transmitted and applied to the EUV equipment.

Differences between a method of configuring an EUV light source according to a present embodiment and a typical method of configuring an EUV light source are as follows.

(i) By generating an initial top-hat illumination system based on a Fourier approximation, optical simulation is efficiently performed only on a necessary portion without the need for optical simulation on the entire area of a pupil. Thus, a turn around time (TAT) of the optimization of an EUV illumination system is reduced.

(ii) The EUV illumination system includes 336 EUV point light sources that are incoherent. Thus, the EUV illumination system is optimized based only on information about a minimum of 336 to a maximum of 1,620 pupil mirrors or location information about EUV point light sources that correspond to the pupil mirrors. In addition, based on intensity information about aerial images obtained in the optical simulation of EUV point light sources in the Fourier approximation top-hat illumination system, an optimum EUV illumination system with excellent performance is implemented according to established rules, for example, a game theory algorithm.

(iii) Various optical parameters are applied to constraints and cost functions or an optimization and are also applied to not only repetitive EUV patterns but also random patterns.

Moreover, of the operations of a typical method of configuring the EUV light source, the most time-consuming bottleneck portion corresponds to an operation of generating aerial images of EUV point light sources via optical simulation. However, in a method of configuring the EUV light source according to a present embodiment, because unnecessary EUV point light sources are removed in about 30 seconds during the generation of the Fourier approximation top-hat illumination system, optical simulation is not performed on all the pupil mirrors but is partially performed to optimize the EUV illumination system. In addition, when a single optical simulation tool is used for 1100 EUV point light sources, it may have a TAT of about 25 minutes to about 30 minutes to optimize the EUV illumination system under one defocus condition. Under 10 defocus conditions, it may have a total TAT of about 5 hours when a single optical simulation tool is used. However, when parallel calculations are performed using a plurality of optical simulation tools, such as 10 optical simulation tools, a total TAT is reduced to about 0.5 hour.

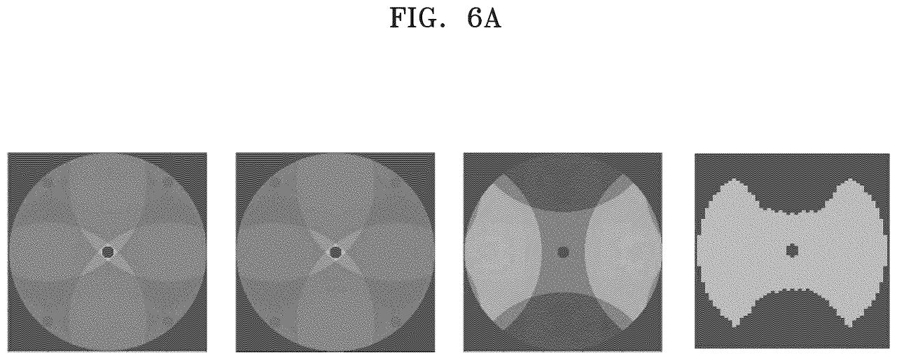

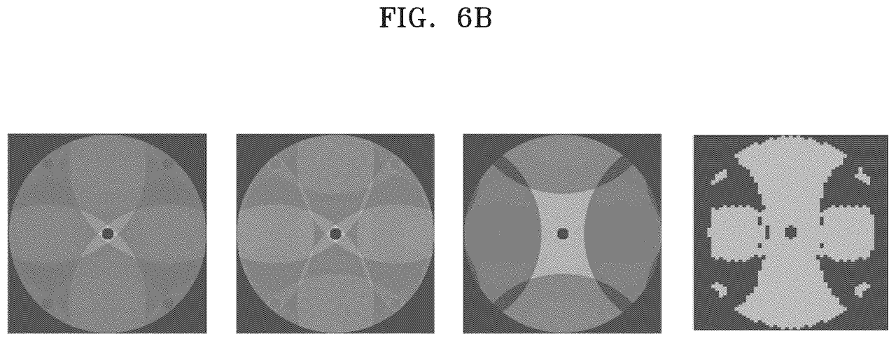

FIG. 4 is a flowchart of generating a Fourier approximation top-hat illumination system in a method of configuring the EUV light source shown in FIG. 1. FIGS. 5A to 5D illustrate the generation of the Fourier approximation top-hat illumination system shown in FIG. 4. FIGS. 6A and 6B illustrate the generation of a different type of Fourier approximation top-hat illumination system. FIGS. 4, 5A to 5D, 6A, and 6B are described with reference to FIG. 1, and repeated descriptions of those presented with reference to FIGS. 1 to 3 may be omitted or summarized.

Referring to FIGS. 4 and 5A, in a method of configuring an EUV light source according to a present embodiment, operation S120 of generating the top-hat illumination system includes, initially, convolving a 2D fast Fourier transform (FFT) of a mask pattern with a pupil to generate a first 2D FFT image (S122). For example, the mask pattern is normalized, and a pupil with a pupil fill ratio (PFR) of 100% is used. A PFR refers to a ratio of an area on which light is incident to a pupil surface. The first 2D FFT image is illustrated in FIG. 5A.

Referring to FIGS. 4 and 5B, in an embodiment, after the first 2D FFT image is generated, a 2D FFT for a target pattern is convolved with a pupil to generate a second 2D FFT image (S124). The target pattern is also normalized, and a pupil with a PFR of 100% is also used to generate the second 2D FFT image. In addition, the target pattern is formed on a wafer and differs from the mask pattern, which is a pattern on a mask. The second 2D FFT image is illustrated in FIG. 5B. For reference, neither of the mask pattern nor the target pattern refer to a shape of an actual pattern, but rather to a shape of an illumination system that corresponds to the mask pattern and the target pattern or a shape of an intensity distribution of the illumination system.

Referring to FIGS. 4, 5C, and 5D, in an embodiment, after the second 2D FFT image is generated, a 2D FFT difference image is obtained by subtracting the second 2D FFT image from the first 2D FFT image (S126). Thereafter, the 2D FFT difference image is rendered (S128). A top-hat illumination system is generated by using a rendering process. The 2D FFT difference image is illustrated in FIG. 5C, and an image of the top-hat illumination system is illustrated in FIG. 5D. In FIG. 5D, the rendering process divides an image into two regions, based on a set reference intensity. Accordingly, in FIG. 5D, regions of the top-hat illumination system are clearly marked as a dark portion and a bright portion.

In FIG. 5C, the bright portion corresponds to a portion with a large intensity difference, and the dark portion corresponds to a portion with a small intensity difference. Accordingly, to implement a target pattern on a wafer, a portion to be emphasized in the pupil surface is identified from FIG. 5C. For example, to form a required target pattern, it can be seen from FIG. 5C which part of the EUV illumination system should actually be illuminated. For example, when locations of EUV point light sources are highlighted, based on the 2D FFT difference image, locations of EUV point light sources for which aerial images are to be calculated can be detected. In principle, the number of EUV point light sources for which aerial images should be calculated is 1620. However, through the above-described Fourier approximation top-hat illumination system, the number of EUV point light sources is adjusted within a range of 336 to 1620, depending on efficiency. For example, in a method of configuring an EUV light source according to a present embodiment, aerial images of about 1100 EUV point light sources are calculated.

FIGS. 6A and 6B show examples of images of a different type of Fourier approximation top-hat illumination system generated using a same process as in FIGS. 5A to 5D.

In a method of configuring an EUV light source according to a present embodiment, after a top-hat illumination system is generated through Fourier approximation, optical simulation is automatically and simultaneously performed by using a macro on the EUV point light sources under several defocus conditions. After the macro is completed, 1D intensity values of gauges for the EUV point light sources are automatically stored, and an EUV illumination system are optimized by combining the 1D intensity values. To optimize the EUV illumination system, a target CD and an NILS are calculated using the stored 1D intensity values. The concepts and calculations of the target CD and the NILS are described below with reference to FIG. 7.

FIG. 7 illustrates the concepts and calculation of a target CD and an NILS in relation to a method of configuring an EUV light source shown in FIG. 1.

Referring to FIG. 7, in an embodiment, the target CD is calculated through CD targeting. CD targeting sets a threshold intensity level TH for an aerial image such that a pattern that corresponds to a required CD value is formed. In CD targeting, a CD of the aerial image includes an offset from an after development inspection (ADI) CD of an actual patterning process. However, because an offset value is constant in a given CD range, a CD value is targeted that considers the constant offset value. In FIG. 7, a target CD calculated by CD targeting on an x-axis is indicated by arrows on both sides. For example, the target CD is calculated by setting the threshold intensity TH on the x-axis.

The NILS is defined as

$$CDx \cdot \frac{dln ( I )}{dx} or . \frac{CDx}{I} \frac{dI}{dx}$$

on the x-axis. For example, the NILS is defined by a CD CDx, an intensity I of the aerial image at a point where the CD CDx is defined, and a differential value dI/dx of the intensity I. The NILS is defined the same way on the y-axis. In FIG. 7, the differential value dI/dx, such as a slope, of the intensity I at the point where the CD CDx is defined is illustrated with a dashed line. As described above, the NILS is an optical parameter that shows that larger NILS values correspond to smaller CD changes in response to process variations, such as a dose and a focus.

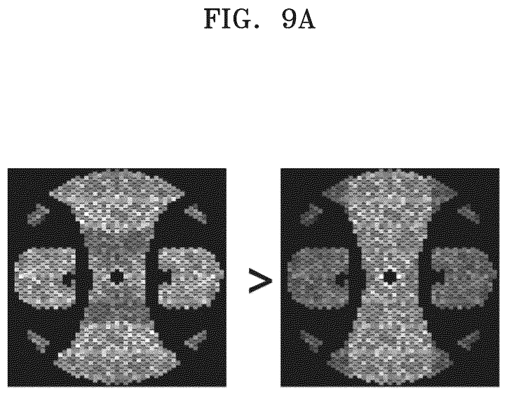

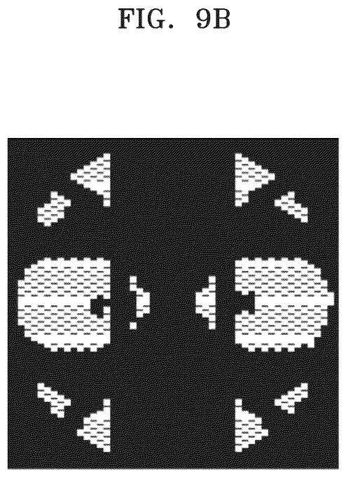

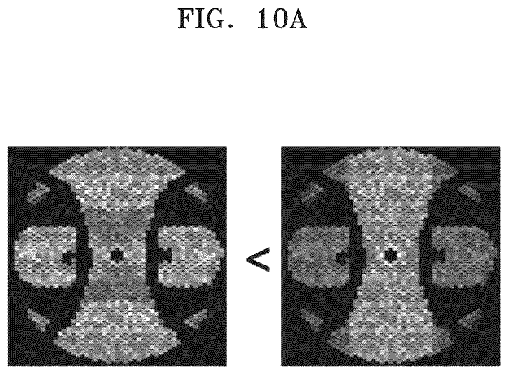

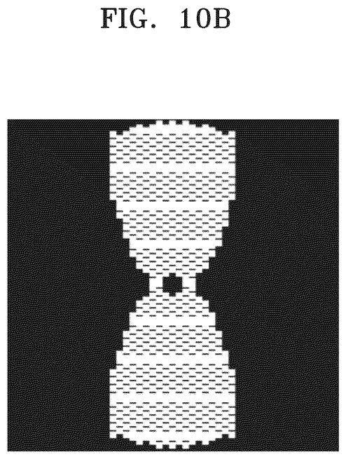

FIG. 8 is a flowchart of an operation of selecting a combination of EUV point light sources in a method of configuring the EUV light source shown in FIG. 1, and FIGS. 9A to 10B illustrate the selection of the combination of EUV point light sources shown in FIG. 8. FIGS. 8 and 9A to 10B are described with reference to FIG. 1, and repeated descriptions of those presented with reference to FIGS. 1 to 7 may be omitted or summarized.

Referring to FIGS. 8 to 10B, in a method of configuring an EUV light source according to a present embodiment, EUV point light sources are selected through a Fourier approximation top-hat illumination system, and information about aerial images of the EUV point light sources is stored. Subsequently, an EUV illumination system is optimized based on an NILS and an intensity that is calculated using the aerial images. When optimizing an EUV illumination system, considering only one optical parameter may violate constraints, such as fixed x-axial and y-axial CD aspect ratios.

However, in a method of configuring an EUV light source according to a present embodiment, the EUV illumination system is optimized while satisfying the constraints by applying predetermined rules, such as from game theory. For example, in a method of configuring an EUV light source according to a present embodiment, the optimization of the EUV illumination system includes selecting a combination of EUV point light sources based on established rules (S140).

For example, operation S140 of selecting a combination of EUV point light sources includes assigning an x-axial intensity and a y-axial intensity to n EUV point light sources (S142). In an embodiment, it is assumed that the fixed x-axial and y-axial CD aspect ratios are the constraints, and the n, where n is a positive integer less than 336, EUV point light sources have already been selected. In addition, it is assumed that the illumination efficiency of the EUV illumination system is set to 1, and locations of 336 EUV point light sources can be found and selected.

After the x-axial intensity and the y-axial intensity are assigned to the n EUV point light sources, the x-axial intensity is compared with the y-axial intensity (S144). In general, some EUV point light sources have a high x-axial intensity, while the remaining EUV point light sources have a high y-axial intensity. Accordingly, when the x-axial intensity and the y-axial intensity are assigned to the selected n EUV point light sources with a fixed target CD, the intensity of the target CD is biased to one side in the EUV illumination system that includes the n EUV point light sources. Thus, an axis that lacks intensity is checked by comparing the x-axial intensity with the y-axial intensity.

After the x-axial intensity is compared with the y-axial intensity, an n+1-th EUV point light source is selected to strengthen the low intensity axis (S146). An illumination system with a high y-axial intensity is illustrated in FIG. 9A. For example, the sum of the left y-axial intensities is greater than the sum of the right x-axial intensities. For example, to increase the x-axial intensity, an optimal location of an n+1-th EUV point light source is selected in a white portion of FIG. 9B. An optimal location is, for example, a location that optimizes or maximizes the NILS. Conversely, an illumination system with a high x-axial intensity is illustrated in FIG. 10A. For example, the sum of the right x-axial intensities is greater than the sum of the left y-axial intensities. For example, to increase the y-axial intensity, an optimal location of an n+1-th EUV point light source is selected in a white portion of FIG. 10B. By selecting a combination of 336 EUV point light sources in the above-described manner, an illumination system with an optimized NILS is completed while maintaining the CD aspect ratio constraint. In addition, although the CD aspect ratio has been described as the constraint, not only the CD aspect ratio but also all optical parameters that can be calculated from an intensity of the aerial image can be used as constraints or optimization targets. For reference, a constraint is a range or value to be observed, and an optimization target is an object for which a maximum value is to be found based on scores.

From experimental results, it can be confirmed that a method of configuring an EUV light source according to a present embodiment has improved an NILS, an intensity, and an IPU value as compared to a typical method of configuring an EUV light source. For example, while maintaining a target CD, a method of configuring an EUV light source according to a present embodiment was confirmed to have about 30% improved NILS and about 20% improved IPU as compared to the typical method of configuring the EUV light source. In addition, in a method according to a present embodiment, about 10% improved dose was confirmed as compared to the typical method of configuring the EUV light source.

A method of configuring an EUV light source according to a present embodiment can be applied to, but is not limited thereto, a repetitive pattern to optimize the EUV illumination system, and can also be applied to a random pattern to optimize the EUV illumination system. In a method of configuring an EUV light source according to a present embodiment, a TAT for optimizing the EUV illumination system is reduced from 30 to 40 minutes to about 10 minutes, depending on the number of optical simulation tools and the number of processors. Furthermore, when the TAT for the optimization is reduced, not only the optimization of the EUV illumination system but also mask optimization can be applied later via mask split optimization, and sequential source mask optimization (SMO) and parallelized SMO can be performed. As a result, a TAT and cost required for the SMO are reduced.

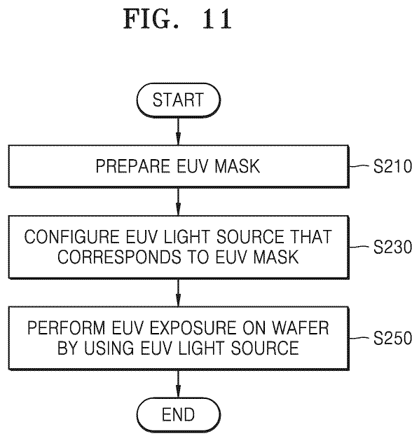

FIG. 11 is a flowchart an EUV exposure method using an EUV light source, according to an embodiment. FIG. 11 is described with reference to FIG. 1, and a repeated descriptions as those presented with reference to FIGS. 1 to 10C may be omitted or summarized.

Referring to FIG. 11, an EUV exposure method using an EUV light source according to a present embodiment, hereinafter referred to as an ‘EUV exposure method’, includes preparing an EUV mask (S210). In an embodiment, the EUV mask is the same as the EUV mask Ms of the EUV equipment described with reference to FIG. 2. However, the preparation of an EUV mask may refer to preparing an EUV mask that includes a specific mask pattern.

After the EUV mask is prepared, an EUV light source that corresponds to the EUV mask is configured (S230). The operation S230 of configuring an EUV light source includes a method of configuring an EUV light source of FIG. 1. Accordingly, several operations described with reference to a method of configuring the EUV light source shown in FIG. 1 are performed, and thus, an optimum EUV illumination system is implemented. In an EUV exposure method according to a present embodiment, the operation S230 of configuring the EUV light source includes configuring the entire EUV optics.

After the EUV light source is configured, an EUV exposure process is performed on a wafer by using the EUV light source (S250). The EUV exposure process includes projecting EUV light onto a photoresist (PR) layer on the wafer. In some embodiments, the EUV exposure process includes developing the PR layer. A PR pattern is formed by developing the PR layer.

In an EUV exposure method according to a present embodiment, the operation S230 of configuring the EUV light source includes a method of configuring an EUV light source described above with reference to FIG. 1. Thus, an optimized EUV illumination system with excellent performance can be implemented, and an optimal EUV exposure process can be performed based on the optimized EUV illumination system. Therefore, a PR pattern that optimally meets a required patterning performance index is formed on the wafer.

While embodiments of the inventive concept have been particularly shown and described with reference to drawings thereof, it will be understood that various changes in form and details may be made therein without departing from the spirit and scope of the following claims.

What is claimed is:

1. A method of configuring an extreme ultraviolet (EUV) light source, the method comprising:
obtaining first information about a mask pattern;
generating a top-hat illumination system for the mask pattern based on a Fourier approximation;
storing second information about aerial images of EUV point light sources that correspond to pupil mirrors;
selecting a combination of the EUV point light sources according to established rules; and
performing a simulation on an entire EUV illumination system based on the selected combination of the EUV point light sources.

2. The method of claim 1, wherein
the EUV point light sources are incoherent and do not interfere with each other,
generating the top-hat illumination system includes dividing the pupil mirrors into first pupil mirrors and second pupil mirrors, wherein the first pupil mirrors are unnecessary for the EUV illumination system, and
storing the second information includes calculating the aerial images by performing an optical simulation on the EUV point light sources that correspond to the second pupil mirrors.

3. The method of claim 1, wherein generating the top-hat illumination system comprises:
generating a first two-dimensional (2D) fast Fourier transform (FFT) image by convolving a 2D FFT for the mask pattern with a pupil,
generating a second 2D FFT image by convolving a 2D FFT for a target pattern with a pupil; and
obtaining a 2D FFT difference image by subtracting the second 2D FFT image from the first 2D FFT image,
wherein a bright portion in the 2D FFT difference image has a large intensity difference and corresponds to a region to be illuminated.

4. The method of claim 3,
wherein the mask pattern and the target pattern are normalized and the pupil has a pupil fill ratio (PFR) of 100%,
wherein generating the top-hat illumination system further comprises rendering the 2D FFT difference image after obtaining the 2D FFT difference image,
wherein the top-hat illumination system is generated by rendering the 2D FFT difference image.

5. The method of claim 1, wherein
the first information comprises a pitch of a repetitive pattern, a target critical dimension (CD), a constraint, and a gauge of the mask pattern, and
the second information comprises an intensity on the gauge, a threshold intensity, and a normalized image log slope (NILS) of the aerial image.

6. The method of claim 5, wherein storing the second information comprises calculating the aerial images via an optical simulation under a plurality of defocus conditions.

7. The method of claim 1, wherein selecting the combination of the EUV point light sources comprises
selecting, according to the established rules, a combination of the EUV point light sources that satisfies a constraint and maximizes an NILS.

8. The method of claim 7,
wherein the constraint is a CD aspect ratio of a target pattern,
wherein selecting the combination of the EUV point light sources comprises:
assigning an x-axial intensity and a y-axial intensity to n EUV point light sources,
wherein n is a positive integer less than the number of EUV point light sources;
comparing the x-axial intensity with the y-axial intensity; and
selecting an n+1-th EUV point light source that strengthens a low intensity axis.

9. The method of claim 1, wherein
the number of pupil mirrors is 1,620,
the EUV illumination system includes assigning 336 pupil mirrors to the EUV point light sources, and
storing the second information comprises calculating the aerial images of the EUV point light sources that correspond to fewer than 1,620 pupil mirrors, based on the top-hat illumination system.

10. The method of claim 1, wherein storing the second information comprises simultaneously calculating the aerial images via a parallelized operation that uses a plurality of optical simulation tools under a plurality of defocus conditions.

11. The method of claim 1, further comprising, after performing the simulation on the entire EUV illumination system,
determining whether the EUV illumination system satisfies a constraint, wherein data about the EUV illumination system is transmitted and applied to EUV equipment when the EUV illumination system satisfies the constraint, and
selecting a new combination of the EUV point light sources when the EUV illumination system does not satisfy the constraint.

12. A method of configuring an extreme ultraviolet (EUV) light source, the method comprising:
obtaining first information about a mask pattern;
generating a top-hat illumination system based on two-dimensional (2D) fast Fourier transform (FFT) images of the mask pattern and a target pattern;
storing second information about aerial images by performing, based on the top-hat illumination system, an optical simulation on EUV point light sources that correspond to some pupil mirrors;
selecting a combination of the EUV point light sources according to established rules that satisfy a constraint and maximize a normalized image log slope (NILS); and
performing a simulation on an entire EUV illumination system based on the selected combination of the EUV point light sources.

13. The method of claim 12, wherein generating the top-hat illumination system comprises:
generating a first 2D FFT image by convolving a 2D FFT for the normalized mask pattern with a pupil with a PFR of 100%;
generating a second 2D FFT image by convolving a 2D FFT for the normalized target pattern with a pupil with a PFR of 100%;
obtaining a 2D FFT difference image by subtracting the second 2D FFT image from the first 2D FFT image; and
rendering the 2D FFT difference image.

14. The method of claim 12,
wherein the constraint is a critical dimension (CD) aspect ratio of the target pattern,
wherein selecting the combination of the EUV point light sources comprises:
assigning an x-axial intensity and a y-axial intensity to n EUV point light sources, wherein n is a positive integer less than the number of EUV point light sources;
comparing the x-axial intensity with the y-axial intensity; and
selecting an n+1-th EUV point light source that strengthen a low intensity axis.

15. The method of claim 12, wherein storing the second information comprises
simultaneously calculating the aerial images via a parallelized operation that uses a plurality of optical simulation tools under a plurality of defocus conditions.

16. An extreme ultraviolet (EUV) exposure method, comprising:
preparing an EUV mask;
configuring an EUV light source that corresponds to the EUV mask; and
performing an EUV exposure on a wafer by using the EUV light source,
wherein configuring the EUV light source comprises:
obtaining first information about a mask pattern;
generating a top-hat illumination system for the mask pattern based on a Fourier approximation;
storing second information about aerial images of EUV point light sources that correspond to pupil mirrors;
selecting a combination of the EUV point light sources according to established rules; and
performing a simulation on an entire EUV illumination system based on the selected combination of the EUV point light sources.

17. The method of claim 16, wherein
generating the top-hat illumination system includes dividing the pupil mirrors into first pupil mirrors and second pupil mirrors, wherein the first pupil mirrors are unnecessary for the EUV illumination system, and
storing the second information comprises calculating the aerial images by performing an optical simulation on the EUV point light sources that correspond to the second pupil mirrors.

18. The method of claim 16, wherein generating the top-hat illumination system comprises:
generating a first 2D FFT image by convolving a 2D FFT for a normalized mask pattern with a pupil with a PFR of 100%;
generating a second 2D FFT image by convolving a 2D FFT for a normalized target pattern with a pupil with a PFR of 100%;
obtaining a 2D FFT difference image by subtracting the second 2D FFT image from the first 2D FFT image; and
rendering the 2D FFT difference image.

19. The method of claim 16, wherein selecting the combination of the EUV point light sources comprises
selecting, according the established rules, a combination of the EUV point light sources that satisfies a constraint and maximizes a normalized image log slope (NILS).

20. The method of claim 16,
wherein the constraint is a critical dimension (CD) aspect ratio of a target pattern,
wherein selecting the combination of the EUV point light sources comprises:
assigning an x-axial intensity and a y-axial intensity to n EUV point light sources, wherein n is a positive integer less than the number of EUV point light sources;
comparing the x-axial intensity with the y-axial intensity; and
selecting an n+1-th EUV point light source that strengthens a low intensity axis.
